(19) United States
(12) Patent Application Publication
(10) Pub. No.: US 2025/0393405 A1
(43) Pub. Date: Dec. 25, 2025

(54) DISPLAY DEVICE AND ELECTRONIC DEVICE INCLUDING THE SAME

(71) Applicant: Samsung Display Co., LTD., Yongin-si (KR)

(72) Inventors: DAYOUNG LEE, Yongin-si (KR); KYONGSUB KIM, Yongin-si (KR); A-Rong LEE, Yongin-si (KR); DONGHOON KWAK, Yongin-si (KR)

(73) Assignee: Samsung Display Co., LTD., Yongin-si (KR)

(21) Appl. No.: 19/095,427

(22) Filed: Mar. 31, 2025

(30) Foreign Application Priority Data
Jun. 20, 2024 (KR) 10-2024-0080250

(51) Int. Cl. H10K 59/122; H10K 59/80

(52) U.S. Cl. CPC H10K 59/122; H10K 59/8792

(57) ABSTRACT

A display device includes a substrate, a transistor disposed on the substrate, a first electrode electrically connected to the transistor, a metal layer disposed on the first electrode, a wall disposed on the metal layer, a light emitting part disposed in an opening formed by the metal layer and the wall, and a second electrode disposed on the light emitting part, wherein the light emitting part has a concave shape in the opening, and the end portion of the metal layer and the end portion of the wall are aligned.

### CROSS-REFERENCE TO RELATED APPLICATION(S)

This application claims priority to and benefits of Korean Patent Application No. 10-2024-0080250 under 35 U.S.C. § 119, filed at the Korean Intellectual Property Office on Jun. 20, 2024, the entire contents of which are incorporated herein by reference.

### BACKGROUND

### 1. Technical Field

Embodiments relate to a display device and an electronic device including the display device.

### 2. Description of the Related Art

A light emitting element is an element in which holes supplied from an anode and electrons supplied from a cathode are combined in an organic emission layer to form excitons, and light is emitted while the excitons are stabilized.

The light emitting element has several merits such as wide viewing angle, fast response speed, thin thickness, and lower power consumption such that the light emitting device is widely applied to various electrical and electronic devices such as a television, a monitor, a mobile phone, etc.

### SUMMARY

Embodiments are intended to provide a display device with improved display quality.

A display device according to an embodiment may include a substrate, a transistor disposed on the substrate, a first electrode electrically connected to the transistor, a metal layer disposed on the first electrode, a wall disposed on the metal layer, a light emitting part disposed in an opening formed by the metal layer and the wall, and a second electrode disposed on the light emitting part, wherein the light emitting part has a concave shape in the opening, and the end portion of the metal layer and the end portion of the wall may be aligned with each other.

The first thickness of the central region of the light emitting part may be substantially equal to the second thickness of the light emitting part that overlaps the metal layer.

The first light emission area of the light emitting part having the first thickness may be in contact with the first electrode.

The second light emission area of the light emitting part having the second thickness may be in contact with the wall.

The light emitting part may include a peripheral area having a thickness smaller than the second thickness.

Using a center portion of the light emitting part as a reference, the first light emission area, the second light emission area, and the peripheral area may be arranged in order.

The first light emission area may be separated from the wall and the metal layer in the thickness direction of the substrate.

The wall may include a first region and a second region stacked in the thickness direction of the substrate.

The side slope of the first region and the side slope of the second region may be different from each other.

The first electrode may include a first sub-layer, a second sub-layer disposed on the first sub-layer, and a third sub-layer disposed on the second sub-layer.

The second sub-layer may include a metal.

The light emitting part may include at least one of a hole injection layer, a hole transport layer, a light emitting layer, and an electron transport layer sequentially stacked on the first electrode.

The light emitting part may include the hole injection layer, the hole transport layer, the light emitting layer, and the electron transport layer, and adjacent light emitting parts between adjacent pixels may be separated from each other by the wall.

A display device according to an embodiment may include a substrate, a transistor disposed on the substrate, a first electrode electrically connected to the transistor, a light absorption layer disposed on the first electrode and including an opening, a wall disposed on the light absorption layer and including an opening, a light emitting part disposed in the opening of the light absorption layer and the opening of the wall, and a second electrode disposed on the light emitting part, wherein the light emitting part has a concave shape in the opening, and the end portion of the light absorption layer and the end portion of the wall may be aligned with each other.

The thickness of a central region of the light emitting part may be substantially equal to the thickness of the light emitting part that overlaps the light absorption layer.

The wall may include a first region and a second region stacked in the thickness direction of the substrate.

A side slope of the first region and a side slope of the second region may be different from each other.

The light absorption layer may include chromium.

The light emitting part may include at least one of a hole injection layer, a hole transport layer, a light emitting layer, and an electron transport layer sequentially stacked on the first electrode.

The light emitting part may include the hole injection layer, the hole transport layer, the light emitting layer and the electron transport layer, and adjacent light emitting parts between the adjacent pixels may be separated from each other by the wall.

An electronic device according to an embodiment may include: a display device to display an image based on input image data, the display device including: a substrate, a transistor disposed on the substrate, a first electrode electrically connected to the transistor, a metal layer disposed on the first electrode, a wall disposed on the metal layer, a light emitting part disposed in an opening formed by the metal layer and the wall, and a second electrode disposed on the light emitting part, wherein the light emitting part may have a concave shape in the opening, and an end portion of the metal layer and an end portion of the wall may be aligned with each other.

A first thickness of a central region of the light emitting part may be substantially equal to a second thickness of the light emitting part that overlaps the metal layer.

A first thickness of a central region of the light emitting part may be substantially equal to a second thickness of the light emitting part that overlaps the metal layer.

A second light emission area of the light emitting part having the second thickness may be in contact with the wall.

The light emitting part may include at least one of a hole injection layer, a hole transport layer, a light emitting layer, and an electron transport layer sequentially stacked on the first electrode.

The electronic device may be at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

According to embodiments, a display device with improved display quality may be provided.

### BRIEF DESCRIPTION OF THE DRAWINGS

FIG. 1 is a schematic exploded perspective view of a display device according to an embodiment.

FIG. 2 is a schematic cross-sectional view of a display panel according to an embodiment.

FIG. 3 is a schematic cross-sectional view of a display panel according to an embodiment.

FIG. 4 and FIG. 5 are each an enlarged schematic view of a region of a display panel according to an embodiment.

FIG. 6 is a schematic cross-sectional view of a display panel according to an embodiment.

FIG. 7 and FIG. 8 are each an enlarged schematic view of a region of a display panel according to an embodiment.

FIG. 9 and FIG. 10 are each an image of a pixel according to a comparative example.

FIG. 11 and FIG. 12 are characteristic graphs according to a comparative example and an embodiment.

FIG. 13 is a block diagram of an electronic device according to an embodiment.

FIG. 14 shows schematic diagrams of electronic devices according to various embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

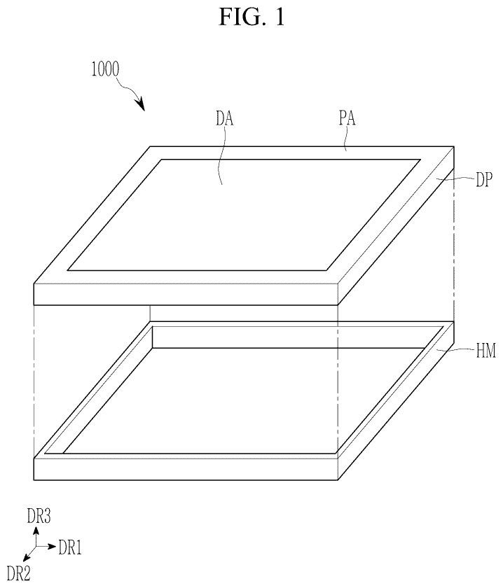

Hereinafter, a display device according to an embodiment is described with reference to FIG. 1. FIG. 1 is a schematic exploded perspective view of a display device according to an embodiment.

Referring to FIG. 1, a display device 1000 according to an embodiment may include a display panel DP and a housing HM.

In the display panel DP, a surface on which an image is displayed is parallel to a plane defined by a first direction DR1 and a second direction DR2. The normal direction of a surface on which the image is displayed (i.e., the thickness direction of the display panel DP) is indicated by a third direction DR3. The front (or an upper surface) and the back (or a lower surface) of each member may be separated by the third direction DR3. However, the directions indicated by the first to third directions DR1, DR2, and DR3 are relative concepts and may be converted to other directions.

The display panel DP may be a flat rigid display panel, and may also be a flexible display panel. However, embodiments are not limited thereto. For example, the display panel DP may be made of a light emitting display panel. However, the type of the display panel DP is not limited thereto, and may be composed of various types of the panels. For example, the display panel DP may be formed as a liquid crystal panel, an electrophoretic display panel, an electrowetting display panel, or the like. For example, the display panel DP may be made of next-generation display panels such as a microlight emitting diode display panel, a quantum dot light emitting diode display panel, and a quantum dot organic light emitting diode display panel.

The micro-light emitting diode (Micro LED) display panel consists of a type in which 10 to 100 micrometer-sized light emitting diodes (LED) compose each pixel. These micro-light emitting diode (LED) display panels have merits such as using inorganic materials, omitting the color filters and backlights, having a fast reaction speed, realizing high luminance with low power, and not breaking when being bent.

The quantum dot light emitting diode display panel may be made by a method of attaching a film containing quantum dots or depositing a material containing quantum dots. The quantum dots may be made of inorganic materials such as indium, cadmium, etc., they emit light by themselves, and may be particles with a diameter of several nanometers or less. By adjusting the particle size of the quantum dots, it is possible to display light of a desired color. The quantum dot organic light emitting diode display panel may be made by a method using a blue organic light emitting diode as a light source, and attaching a film including red and green quantum dots thereon or depositing a material including red and green quantum dots to implement a color. The display panel DP according to an embodiment may be formed of various display panels.

As shown in FIG. 1, the display panel DP may include a display area DA in which an image is displayed, and a non-display area PA adjacent to the display area DA. The non-display area PA may be an area where an image is not displayed. The display area DA may have a rectangular shape, for example, and the non-display area PA may have a shape surrounding the display area DA. However, embodiments are not limited thereto, and the shapes of the display area DA and the non-display area PA may be relatively designed.

The housing HM may provide a selected interior space. The display panel DP may be mounted inside the housing HM. In addition to the display panel DP, various electronic components, for example, a power supply unit, a storage device, and a sound input and output module, may be mounted inside the housing HM.

A light emitting display device 1000 according to an embodiment may be a device for displaying a motion picture or a still image, and may be used as a display screen of various products such as a television, a laptop, a monitor, an advertisement board, Internet of Things (IoT), etc. as well as portable electronic devices such as a mobile phone, a smart phone, a tablet personal computer, a mobile communication terminal, an electronic notebook, an e-book, a portable multimedia player (PMP), a navigation device, an ultramobile PC (UPMC), etc. For example, the display device 1000 according to an embodiment may be used in a wearable device such as a smart watch, a watch phone, a glasses display, and a head mounted display (HMD). For example, the display device 1000 according to an embodiment may be used as an instrument panel of a car, and a center fascia of the car or a center information display (CID) disposed on a dashboard, a room mirror display that replaces a side mirror of the car, an entertainment device for a rear seat of the car, or a display disposed on the rear surface of the front seat.

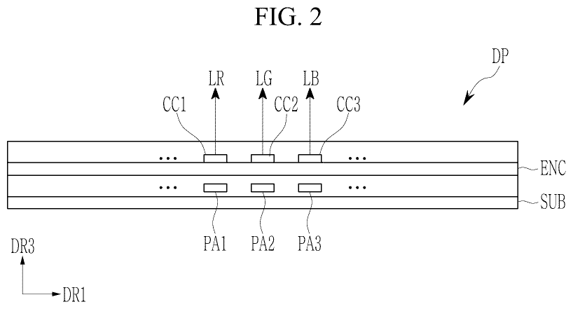

Hereinafter, the display area of the display panel according to an embodiment may be described with reference to FIG. 2. FIG. 2 is a schematic cross-sectional view of a display panel according to an embodiment.

In addition to FIG. 1, referring to FIG. 2, the display panel DP may have a plurality of pixels PA1, PA2, and PA3 arranged on a substrate SUB corresponding to the display area DA of FIG. 1. Each of the pixels PA1, PA2, and PA3 may include a plurality of transistors and a light emitting element connected thereto. The shape and arrangement of each pixel of the plurality of pixels PA1, PA2, and PA3 may be varied.

An encapsulation layer ENC may be disposed on the plurality of pixels PA1, PA2, and PA3. The display area DA may be protected from external air or moisture through the encapsulation layer ENC. The encapsulation layer ENC may be provided integrally to overlap the entire surface of the display area DA, and may also be partially placed on the non-display area PA.

A first color filter part CC1, a second color filter part CC2, and a third color filter part CC3 may be disposed on the encapsulation layer ENC. The first color filter part CC1 may overlap the first pixel PA1, the second color filter part CC2 may overlap the second pixel PA2, and the third color filter part CC3 may overlap the third pixel PA3.

The light emitted from the first pixel PA1 may pass through the first color filter part CC1 to provide a red light LR. The light emitted from the second pixel PA2 may pass through the second color filter part CC2 to provide a green light LG. The light emitted from the third pixel PA3 may pass through the third color filter part CC3 to provide a blue light LB.

The first color filter part CC1 may include a color filter or a color conversion layer including quantum dots. The second color filter part CC2 may include a color filter or a color conversion layer including quantum dots. The third color filter part CC3 may include a color filter or a transparent polymer resin layer.

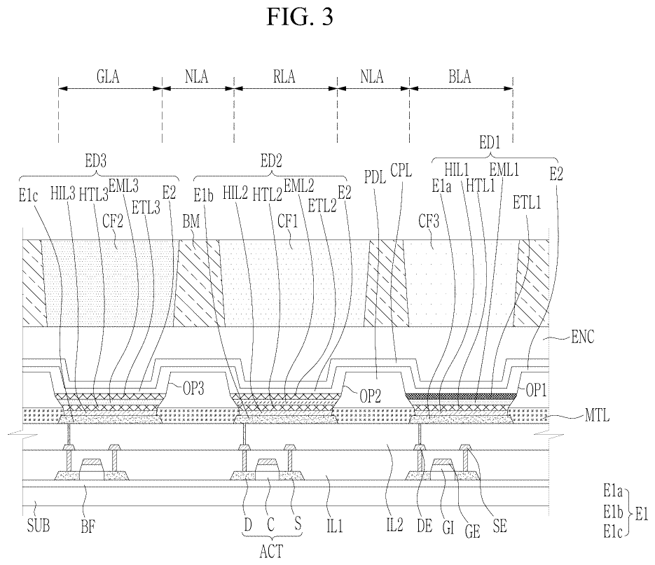

Below, the specific stacking structure of the display panel according to an embodiment is described with reference to FIG. 3. FIG. 3 is a schematic cross-sectional view of a display panel according to an embodiment.

Referring to FIG. 3, a display device according to an embodiment may include a red-light emission area RLA, a green-light emission area GLA, and a blue-light emission area BLA. A non-light emission area NLA may be disposed between the red-light emission area RLA, the green-light emission area GLA, and the blue-light emission area BLA. Each light emission area may correspond to a pixel. For example, the blue-light emission area BLA, the red-light emission area RLA, and the green-light emission area GLA may correspond to the blue pixel, the red pixel, and the green pixel, respectively. The shape and arrangement of each of the red-light emission area RLA, the green-light emission area GLA, and the blue-light emission area BLA may be varied in various ways.

The display device according to an embodiment may include the substrate SUB. The substrate SUB may include a flexible material such as plastic that is bendable, foldable, or rollable, or may include a rigid substrate.

A buffer layer BF may be disposed on the substrate SUB. In another example, the buffer layer BF may be omitted. The buffer layer BF may include silicon nitride (SiNₓ), silicon oxide (SiO₂) or silicon oxynitride (SiOₓN_{y}), and the like. The buffer layer BF may be disposed between the first substrate SUB and the semiconductor layer ACT, thereby improving a characteristic of polycrystalline silicon and to reduce stress applied to the semiconductor layer ACT formed on the buffer layer BF by blocking impurities from the substrate SUB and flattening the first substrate SUB during a crystallization process for forming the polycrystalline silicon.

The semiconductor layer ACT may be disposed on the buffer layer BF. The semiconductor layer ACT may be made of polycrystalline silicon or oxide semiconductor. The semiconductor layer ACT may include a channel area C, a source area S, and a drain area D. The source area S and the drain area D may be located on either side of the channel area C. The channel area C may be an intrinsic semiconductor that is not doped or is barely doped with an impurity, and the source area S and the drain area D may be impurity semiconductors that are doped with a conductive impurity. The semiconductor layer ACT may be composed of an oxide semiconductor, in which case a separate protective layer is added to protect the oxide semiconductor material, which is vulnerable to external environments such as high temperatures.

A gate insulating layer GI may be disposed on the semiconductor layer ACT. The gate insulating layer GI may be a single layer or a multilayer including at least one of silicon nitride (SiNₓ), silicon oxide (SiO₂), and silicon oxynitride (SiOₓN_{y}).

A gate electrode GE may be disposed on the gate insulating layer GI, and the gate electrode GE may be a multilayer in which a metal layer including any one of copper (Cu), copper alloy, aluminum (Al), aluminum alloy, molybdenum (Mo), and molybdenum alloy is stacked.

An interlayer insulating layer IL1 may be disposed on the gate electrode GE and the gate insulating layer GI. The interlayer insulating layer IL1 may include silicon nitride (SiNₓ), silicon oxide (SiO₂) or silicon oxynitride (SiOₓN_{y}). In the interlayer insulating layer IL1, openings may be disposed to expose the source area S and the drain area D, respectively.

A source electrode SE and a drain electrode DE may be disposed on the interlayer insulating layer IL1. The source electrode SE and the drain electrode DE may be respectively connected to the source area S and the drain area D of the semiconductor layer ACT through openings formed in the interlayer insulating layer IL1.

A passivation layer IL2 may be disposed on the interlayer insulating layer IL1, the source electrode SE, and the drain electrode DE. The passivation layer IL2 may cover and planarizes the interlayer insulating layer IL1, the source electrode SE, and the drain electrode DE, so that first electrodes E1a, E1b, and E1c may be formed without steps on the passivation layer IL2. The passivation layer IL2 may be formed of a stacked layer of an organic material such as polyacrylate resin, polyimide resin, or the like, or a stacked layer of an organic material and an inorganic material.

The first electrodes E1a, E1b, and E1c may be disposed on the passivation layer IL2. The first electrodes E1a, E1b, and E1c may be electrically connected to the drain electrode DE through the opening in the passivation layer IL2.

The driving transistor, consisting of the gate electrode GE, the semiconductor layer ACT, the source electrode SE, and the drain electrode DE, may be connected to each first electrode E1a, E1b, and E1c and may supply a driving current to each light emitting element ED1, ED2, and ED3. The display device according to an embodiment, in addition to the driving transistor shown in FIG. 3, may further include a switching transistor that is connected to the data line and transmits the data voltage in response to a scan signal, and a compensation transistor that is connected to the driving transistor and responds to the scan signal to compensate for the threshold voltage of the driving transistor.

A metal layer MTL may be disposed on the first electrodes E1a, E1b, and E1c and the passivation layer IL2. The metal layer MTL may be disposed on at least a portion of the first electrode E1. The metal layer MTL may overlap the non-light emission area NLA. The metal layer MTL may overlap a wall (or partition wall) PDL and a light shielding layer BM described later.

The metal layer MTL may include a metal, for example, aluminum, silver, copper, gold, etc.

The wall PDL may be disposed on the metal layer MTL. The wall PDL and the metal layer MTL may have openings OP1, OP2, and OP3 that overlap the first electrodes E1a, E1b, and E1c, respectively. The metal layer MTL and the wall PDL may include a first opening OP1 that overlaps the blue-light emission area BLA, a second opening OP2 that overlaps the red-light emission area RLA, and a third opening OP3 that overlaps the green-light emission area GLA.

The openings OP1, OP2, and OP3 may have a planar shape almost similar to the first electrodes E1a, E1b, and E1c, and may have a planar rhombus or an octagonal shape similar to a rhombus, and may have any shape such as a quadrangle or a polygon. However, embodiments are not limited thereto.

The wall PDL may include organic materials such as polyacryl-based resin (polyacrylate resin), polyimide-based resin (polyimide resin), or inorganic materials such as silica.

The metal layer MTL and the wall PDL may be manufactured using the same mask. After forming the wall PDL by using one mask, the metal layer MTL may be formed using the formed wall PDL as a reference. The metal layer MTL may be formed through either a wet etching process or a dry etching process.

The metal layer MTL may be disposed on at least a portion of the first electrodes E1a, E1b, and E1c, and the wall PDL may be disposed on the metal layer MTL. The metal layer MTL may be in contact with at least part of the first electrodes E1a, E1b, and E1c. The metal layer MTL may have a shape surrounding the edge portion of the first electrodes E1a, E1b, and E1c.

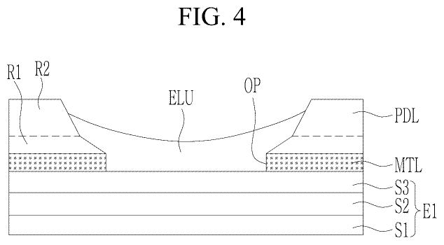

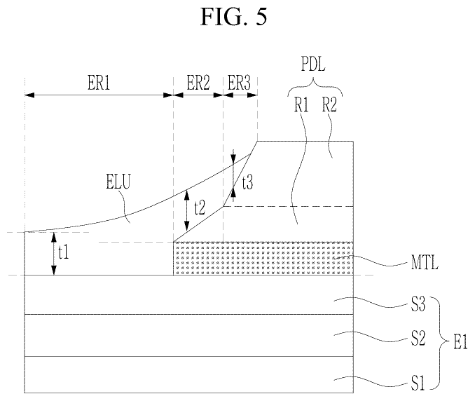

The morphology of the metal layer MTL and the wall PDL may be examined in more detail with reference to FIG. 4 and FIG. 5. FIG. 4 and FIG. 5 are schematic views schematically showing one component among the red-light emission area, the green-light emission area, and the blue-light emission area described above.

Referring to FIG. 4 and FIG. 5 in addition to FIG. 3, the first electrode E1 according to an embodiment may include a first sub-layer S1, a second sub-layer S2, and a third sub-layer S3. According to an embodiment, the first sub-layer S1 and the third sub-layer S3 may include a transparent metal oxide, for example, at least one of indium tin oxide (ITO), indium zinc oxide (IZO), and zinc oxide (ZnO). The second sub-layer S2 may include silver (Ag), aluminum (Al), chromium (Cr), molybdenum (Mo), tungsten (W), titanium (Ti), gold (Au), palladium (Pd) or an alloy thereof. According to an embodiment, the first electrode E1 may have a triple-layer structure of indium tin oxide/silver/indium tin oxide.

The edge portion of the metal layer MTL may be aligned with the edge portion of the wall PDL. The edge portion of the metal layer MTL and the edge portion of the wall PDL may overlap each other. The aperture shape provided by the metal layer MTL and the aperture shape provided by the wall PDL may be substantially the same as each other. The metal layer MTL and the wall PDL may be formed using the same mask.

The wall PDL may include a first area R1 and a second area R2 adjacent along the thickness direction of the substrate SUB. The second area R2 may be disposed on the first area R1. The first area R1 may be in contact with the metal layer MTL, and the second area R2 may be in contact with the first area R1.

The side of the first area R1 and the side of the second area R2 may have different slopes. The slope of the side of the first area R1 may be smaller than the slope of the side of the second area R2. The side of the wall PDL, where the first area R1 and the second area R2 are combined, may have a single curved shape. The edge portion of the first area R1 may be protruded toward the center portion of the opening OP more than (or beyond) the edge portion of the second area R2.

A light emitting part ELU may be placed in the opening OP of the metal layer MTL and the wall PDL. The light emitting part ELU may have a concave shape in the opening OP. The light emitting part ELU may include at least one of a hole transport layer (HTL), a hole injection layer (HIL), a light emitting layer, and an electron transport layer (ETL), which will be described later. Each layer will be described in more detail later. According to an embodiment, at least one of the hole transport layer (HTL), the hole injection layer (HIL), the light emitting layer, and the electron transport layer (ETL) included in the light emitting part ELU may be omitted.

The light emitting part ELU according to an embodiment may be formed by an inkjet process. The light emitting part ELU may be provided by dripping and drying an ink to form the light emitting part ELU in the opening OP of the metal layer MTL and the wall PDL. For example, the light emitting part ELU formed through the inkjet process may have a concave shape in the opening OP. In one opening OP, the level of the end portion of the light emitting part ELU may be higher than the level of the center portion of the light emitting part ELU. For example, the distance between the end portion of the light emitting part ELU and the upper surface of the first electrode E1 may be greater than the distance between the center portion of the light emitting part ELU and the upper surface of the first electrode E1.

For example, as shown in FIG. 5, the light emitting part ELU may include a first light emission area ER1 having a first thickness t1, a second light emission area ER2 having a second thickness t2, and a peripheral area ER3 having a third thickness t3.

The first light emission area ER1 may overlap the center portion of the opening OP. The first light emission area ER1 may be in direct contact with the first electrode E1. The second light emission area ER2 may be adjacent to the first light emission area ER1. The second light emission area ER2 may overlap the metal layer MTL and a part of the first area R1. The second light emission area ER2 may be in contact the wall PDL. The peripheral area ER3 may be adjacent to the second light emission area ER2. The peripheral area ER3 may overlap the second area R2.

Using the center portion of the light emitting part ELU as a reference, the first light emission area ER1, the second light emission area ER2, and the peripheral area ER3 may be arranged in that order. The first light emission area ER1 may be surrounded by the second light emission area ER2, and the second light emission area ER2 may be surrounded by the peripheral area ER3.

The second thickness t2 of the second light emission area ER2 and the first thickness t1 of the first light emission area ER1 may be substantially the same as each other. In this specification, substantially the same may include a difference of about 5% or less, or an error range of about 10% or less.

The third thickness t3 of the peripheral area ER3 may be smaller than the second thickness t2. According to an embodiment, the first thickness t1 and the second thickness t2 may be thicknesses at which a resonance occurs, and the third thickness t2 may be a thickness at which a resonance does not occur.

According to an embodiment, holes and electrons may originate from the first electrode E1 and the second electrode E2 and meet at the light emitting part ELU to generate light. For example, some light may be emitted through the second electrode E2. For example, the light spread in the substrate SUB direction may collide with the second sub-layer S2 of the first electrode E1 and be emitted back toward the user.

The reflected lights in this way may interfere with each other, and when this happens, a constructive interference may occur and a resonance phenomenon may occur. To have this resonance phenomenon, the light emitting part ELU may have the first thickness t1 or the second thickness t2 of the light emitting part ELU.

Since the light emitting part ELU formed through the inkjet process has the concave shape, it is difficult to have a uniform thickness, such as the thickness of the center portion of the light emitting part ELU, in the opening OP of the wall PDL.

However, the display device according to an embodiment may improve light emission efficiency by providing the metal layer MTL, thereby enabling the light emission and the resonance in the light emitting part ELU that overlaps the metal layer MTL and the wall PDL.

Again referring to FIG. 3, the first light emitting element ED1 according to the embodiment may overlap the blue-light emission area BLA, the second light emitting element ED2 may overlap the red-light emission area RLA, and the third light emitting element ED3 may overlap the green-light emission area GLA.

The first light emitting element ED1 may include a first electrode E1a, a first hole injection layer HIL1, a first hole transport layer HTL1, a first light emitting layer EML1, a first electron transport layer ETL1, and a second electrode E2.

The second light emitting element ED2 may include a first electrode E1b, second hole injection layer HIL2, a second hole transport layer HTL2, a second light emitting layer EML2, a second electron transport layer ETL2, and a second electrode E2.

The third light emitting element ED3 may include a first electrode E1c, a third hole injection layer HIL3, a third hole transport layer HTL3, a third light emitting layer EML3, a third electron transport layer ETL3, and a second electrode E2.

The first opening OP1 and the first electrode E1a of the first light emitting element ED1 may overlap, the second opening OP2 and the first electrode E1b of the second light emitting element ED2 may overlap, and the third opening OP3 and the first electrode E1c of the third light emitting element ED3 may overlap each other. At least a part of the first electrode E1a of the first light emitting element ED1, the first electrode E1b of the second light emitting element ED2, and the first electrode E1c of the third light emitting element ED3 may overlap the wall PDL. With respect to the wall PDL, the first electrode E1a of the first light emitting element ED1, the first electrode E1b of the second light emitting element ED2, and the first electrode E1c of the third light emitting element ED3 may be spaced apart from each other.

The first hole injection layer HIL1 may be disposed on the first electrode E1a of the first light emitting element ED1, the second hole injection layer HIL2 may be disposed on the first electrode E1b of the second light emitting element ED2, and the third hole injection layer HIL3 may be disposed on the first electrode E1c of the third light emitting element ED3. With respect to the wall PDL, the first hole injection layer HIL1, the second hole injection layer HIL2, and the third hole injection layer HIL3 may be separated from each other. The first hole injection layer HIL1 may be disposed in the first opening OP1, the second hole injection layer HIL2 may be disposed in the second opening OP2, and the third hole injection layer HIL3 may be disposed in the third opening OP3.

Each of the first hole injection layer HIL1, the second hole injection layer HIL2, and the third hole injection layer HIL3 may be formed through the inkjet process. The first hole injection layer HIL1, the second hole injection layer HIL2, and the third hole injection layer HIL3 may include the same material, and may each include different materials. However, embodiments are not limited thereto.

Each of the first hole injection layer HIL1, the second hole injection layer HIL2, and the third hole injection layer HIL3 may include hole injection material. The hole injection material may include phthalocyanine compounds such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′4″-Tris (N,N-diphenylamino)triphenylamine), 2-TNATA (4,4′,4″-tris {N,-(2-naphthyl)-N-phenylamino}-triphenylamine), PEDOT/PSS (Poly (3,4-ethylenedioxythiophene)/Poly (4-styrenesulfonate)), PANI/DBSA (Polyaniline/Dodecyl benzenesulfonic acid), PANI/CSA (Polyaniline/Camphor sulfonic acid), PANI/PSS (Polyaniline/Poly (4-styrenesulfonate)), NPB (N,N′-di(naphthalene-1-yl)-N,N′-diphenyl-benzidine), NPD (N,N′-Di (1-naphthyl)-N,N′-diphenyl-(1,1′-biphenyl)-4,4′-diamine), polyether ketone (TPAPEK) including triphenylamine, 4-Isopropyl-4′-methyldiphenyliodonium [Tetrakis(pentafluoro phenyl) borate], HAT-CN (dipyrazino[2,3-f: 2′,3′-h]quinoxaline-2,3,6,7,10,11-hexacarbonitrile) and the like.

The first hole transport layer HTL1 may be disposed on the first hole injection layer HIL1, the second hole transport layer HTL2 may be disposed on the second hole injection layer HIL2, and the third hole transport layer HTL3 may be disposed on the third hole injection layer HIL3. The first hole transport layer HTL1, the second hole transport layer HTL2, and the third hole transport layer HTL3 may be separated from each other relative to the wall PDL. The first hole transport layer HTL1 may be disposed in the first opening OP1, the second hole transport layer HTL2 may be disposed in the second opening OP2, and the third hole transport layer HTL3 may be disposed in the third opening OP3.

Each of the first hole transport layer HTL1, the second hole transport layer HTL2, and the third hole transport layer HTL3 may be formed through the inkjet process. The first hole transport layer HTL1, the second hole transport layer HTL2, and the third hole transport layer HTL3 may include the same material, and may each contain different materials. However, embodiments are not limited thereto.

Each of the first hole transport layer HTL1, the second hole transport layer HTL2, and the third hole transport layer HTL3 may include a hole transport material. The hole transport material may include a carbazole-based derivative such as N-phenylcarbazole and polyvinylcarbazole, a fluorine-based derivative, and a triphenylamine-based derivative such as TPD (N,N′-bis(3-methylphenyl)-N,N′-diphenyl-[1,1-biphenyl]-4,4′-diamine) and TCTA (4,4′,4″-tris(N-carbazolyl)triphenylamine), NPB (N,N′-di(1-naphthyl)-N,N′-diphenylbenzidine), TAPC (4,4′-cyclohexylidene bis[N,N-bis(4-methylphenyl)benzenamine]), HMTPD (4,4′-Bis[N,N′-(3-tolyl)amino]-3,3′-dimethylbiphenyl), mCP (1,3-Bis(N-carbazolyl)benzene), CzSi (9-(4-tert-Butylphenyl)-3,6-bis(triphenylsilyl)-9H-carbazole), m-MTDATA (4,4′,4″-[tris(3-methylphenyl)phenylamino]triphenylamine), and the like.

The first light emitting layer EML1 may be disposed on the first hole transport layer HTL1, the second light emitting layer EML2 may be disposed on the second hole transport layer HTL2, and the third light emitting layer EML3 may be disposed on the third hole transport layer HTL3. The first light emitting layer EML1, the second light emitting layer EML2, and the third light emitting layer EML3 may be spaced apart from each other relative to the wall PDL. The first light emitting layer EML1 may be disposed in the first opening OP1, the second light emitting layer EML2 may be disposed in the second opening OP2, and the third light emitting layer EML3 may be disposed in the third opening OP3. Each of the first light emitting layer EML1, the second light emitting layer EML2, and the third light emitting layer EML3 may be manufactured through an inkjet process.

The first light emitting layer EML1 may emit blue light. The first light emitting layer EML1 may include an organic material, and may be made of a particularly low-molecular organic material or a polymer organic material having a molecular weight of 10,000 or more, such as PEDOT (Poly 3,4-ethylenedioxythiophene).

The second light emitting layer EML2 may emit red light. The second light emitting layer EML2 may include a first quantum dot. The third light emitting layer EML3 may emit green light. The third light emitting layer EML3 may include a second quantum dot. However, without being limited to this embodiment, the second light emitting layer EML2 and the third light emitting layer EML3 may emit red light and green light, respectively, without including quantum dots.

A first electron transport layer ETL1 may be disposed on the first light emitting layer EML1, a second electron transport layer ETL2 may be disposed on the second light emitting layer EML2, and a third electron transport layer ETL3 may be disposed on the third light emitting layer EML3. The first electron transport layer ETL1, the second electron transport layer ETL2, and the third electron transport layer ETL3 can be separated by using the wall PDL as a reference. The first electron transport layer ETL1 may be disposed in the first opening OP1, the second electron transport layer ETL2 may be disposed in the second opening OP2, and the third electron transport layer ETL3 may be disposed in the third opening OP3.

The first electron transport layer ETL1, the second electron transport layer ETL2, and the third electron transport layer ETL3 may each be formed through the inkjet process. The first electron transport layer (ETL) ELT1, the second electron transport layer ETL2, and the third electron transport layer ETL3 according to an embodiment may include the same electron transport material or may include different electron transport materials.

The first electron transport layer (ETL) ELT1, the second electron transport layer ETL2, and the third electron transport layer ETL3 may include an electron transport material, and may include a triazine compound or an anthracene compound according to an embodiment. However, embodiments are not limited thereto, the electron transport material, for example, may include Alq3 (Tris(8-hydroxyquinolinato)aluminum), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-ylphenyl)-9,10-dinaphthylanthracene, TPBi (1,3,5-tris(1-phenyl-1H-benzo[d]imidazol-2-yl)benzene), BCP (2,9-Dimethyl-4,7-diphenyl-1,10-phenanthroline), Bphen (4,7-Diphenyl-1,10-phenanthroline), TAZ (3-(4-Biphenylyl)-4-phenyl-5-tert-butylphenyl-1,2,4-triazole), NTAZ (4-(Naphthalen-1-yl)-3,5-diphenyl-4H-1,2,4-triazole), tBu-PBD (2-(4-Biphenylyl)-5-(4-tert-butylphenyl)-1,3,4-oxadiazole), BAlq (Bis (2-methyl-8-quinolinolato-N1,O8)-(1,1′-Biphenyl-4-olato)aluminum), Bebq2 (berylliumbis(benzoquinolin-10-olate), ADN (9,10-di(naphthalene-2-yl) anthracene), TSPO1 (diphenyl (4-(triphenylsilyl)phenyl)phosphine oxide), TPM-TAZ (2,4,6-Tris(3-(pyrimidin-5-yl)phenyl)-1,3,5-triazine), and a mixture thereof. In another example, the second electron transport layer ETL2 and the third electron transport layer ETL3 may include zinc magnesium oxide (ZnMgO).

The second electrode E2 may be disposed on the first electron transport layer ETL1, the second electron transport layer ETL2, and the third electron transport layer ETL3. The second electrode E2 may be disposed sequentially across the blue-light emission area (BLA), red-light emission area (RLA), green-light emission area (GLA), and non-light emission area NLA. The second electrode E2 may receive a common voltage through a common voltage transmission unit of the non-display area.

Here, the first electrodes E1a, E1b, and E1c may be anodes, which are hole injection electrodes, and the second electrode E2 may be cathode, which is an electron injection electrode. However, embodiments are not limited thereto, and according to a driving method of the display device, the first electrodes E1a, E1b, and E1c may become cathodes, and the second electrode E2 may become an anode.

A capping layer CPL may be disposed on the second electrode E2. An encapsulation layer ENC may be disposed on the capping layer CPL. The encapsulation layer ENC may seal the display layer by covering not only the upper surface but also the side surfaces of the display layer including the light emitting elements ED1, ED2, and ED3.

Since the light emitting element is very vulnerable to moisture and oxygen, the encapsulation layer ENC may seal the display layer and may block the inflow of external moisture and oxygen. The encapsulation layer ENC may include a plurality of layers, and may be formed as a composite film including both an inorganic film and an organic film, or may be formed as a triple layer in which a first inorganic film, an organic film, and a second inorganic film are sequentially formed.

Color filters CF1, CF2, and CF3 and a light-shielding layer BM may be disposed on the encapsulation layer ENC. The red-light emission area RLA may overlap the red color filter CF1, the green-light emission area GLA may overlap the green color filter CF2, and the blue-light emission area BLA may overlap the blue color filter CF3. The non-light emission area NLA may overlap the light-shielding layer BM.

The display device according to an embodiment may increase the amount of light emitted by increasing the area of the light emitting part having the resonant thickness by providing the light emitting part that overlaps the reflective layer.

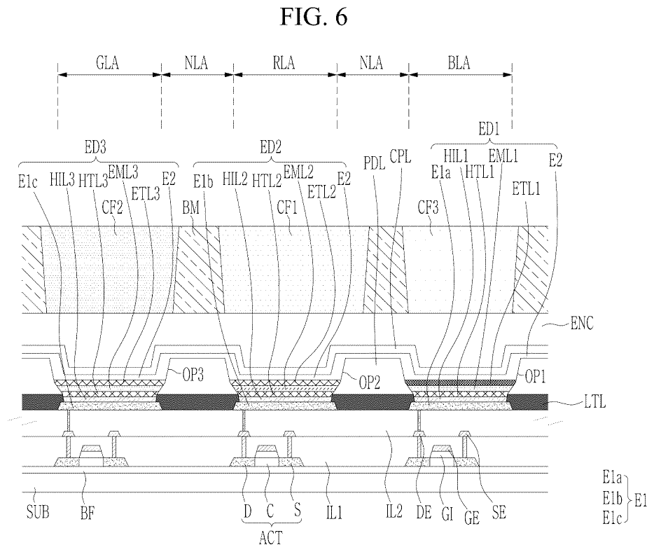

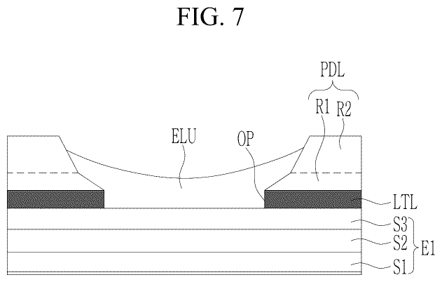

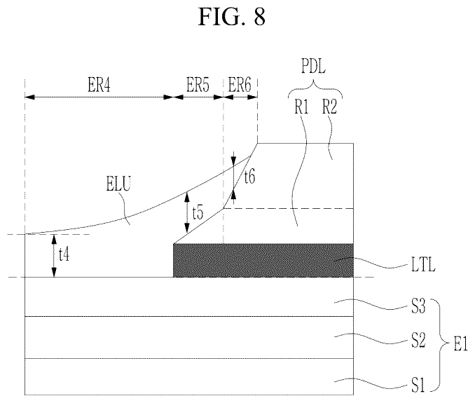

For example, the display device according to an embodiment is described with reference to FIG. 6 to FIG. 8. FIG. 6 is a schematic cross-sectional view of a display panel according to an embodiment. FIG. 7 and FIG. 8 are each an enlarged schematic view of a region of a display panel according to an embodiment. Descriptions of components that are identical to the components described above will be omitted.

Referring first to FIG. 6, a light absorption layer LTL may be disposed on the first electrode E1. The light absorption layer LTL may include a material that absorbs light, and may include chromium as an example.

The light absorption layer LTL may be disposed on at least part of the first electrodes E1a, E1b, and E1c, and the wall PDL may be disposed on the light absorption layer LTL. The light absorption layer LTL may be in contact with at least some of the first electrodes E1a, E1b, and E1c. The light absorption layer LTL may have a form surrounding the edge portions of the first electrodes E1a, E1b, and E1c.

The light absorption layer LTL may overlap the non-light emission area NLA. The light absorption layer LTL may overlap the wall PDL and the light shielding layer BM.

The edge portions of the light absorption layer LTL may be aligned with the edge portions of the wall PDL. The edge portion of the light absorption layer LTL and the edge portion of the wall PDL may overlap each other. The aperture shape provided by the light absorption layer LTL and the aperture shape provided by the wall PDL may be substantially the same as each other.

Further referring to FIG. 7 and FIG. 8, the wall PDL may be disposed on the light absorption layer LTL. The wall PDL and the light absorption layer LTL may have an opening OP that overlaps the first electrode E1. A light absorption layer LTL may be disposed on at least a portion of the first electrode E1.

The wall PDL may include a first area R1 and a second area R2 adjacent along the thickness direction of the substrate SUB. The second area R2 may be disposed on the first area R1.

The side of the first area R1 and the side of the second area R2 may have different slopes. The slope of the side of the first area R1 may be smaller than the slope of the side of the second area R2. The side of the wall PDL, where the first area R1 and the second area R2 are combined, may have a single curved shape. The edge portion of the first area R1 may be protruded toward the center portion of the opening OP more than the edge portion of the second area R2.

The light emitting part ELU may be placed in the opening OP of the light absorption layer LTL and the wall PDL. The light emitting part ELU may have the concave shape in the opening OP. The light emitting part ELU may include at least one of a hole transport layer (HTL), a hole injection layer (HIL), a light emitting layer, and an electron transport layer (ETL), with reference to the previous embodiment for further details. According to an embodiment, at least one of the hole transport layer (HTL), the hole injection layer (HIL), the light emitting layer, and the electron transport layer (ETL) included in the light emitting part ELU may be omitted. For example, adjacent light emitting parts ELU between adjacent pixels may be spaced apart from each other by the wall PDL.

The light emitting part ELU according to an embodiment may be formed by an inkjet process. The light emitting part ELU may be provided by dripping and drying ink to form the light emitting part ELU in the opening OP of the metal layer MTL and the wall PDL. For example, the light emitting part ELU formed through the inkjet process may have a concave shape in the opening OP. In one opening OP, the level of the end portion of the light emitting part ELU may be higher than the level of the center portion of the light emitting part ELU. For example, the distance between the end portion of the light emitting part ELU and the upper surface of the first electrode E1 may be greater than the distance between the center portion of the light emitting part ELU and the upper surface of the first electrode E1.

Referring to FIG. 8, the light emitting part ELU may include a fourth light emission area ER4 having a fourth thickness t4, a fifth light emission area ER5 having a fifth thickness t5, and a peripheral area ER6 having a sixth thickness t6.

The fourth light emission area ER4 may overlap the center portion of the aperture. The fourth light emission area ER4 may be in direct contact with the first electrode E1. The fifth light emission area ER5 may be adjacent to the fourth light emission area ER4. The fifth light emission area ER5 may overlap the light absorption layer LTL and a part of the first area R1. The fifth light emission area ER5 may be in contact with the wall PDL. The peripheral area ER6 may be adjacent to the fifth light emission area ER5.

Based on the center portion of the light emitting part ELU, they may be arranged in the following order: fourth light emission area ER4, fifth light emission area ER5, and peripheral area ER6. The fourth light emission area ER4 may be surrounded by the fifth light emission area ER5, and the fifth light emission area ER5 may be surrounded by the peripheral area ER6.

The fifth thickness t5 of the fifth light emission area ER5 and the fourth thickness t4 of the fourth light emission area ER4 may be substantially the same as each other. The sixth thickness t6 of the peripheral area ER6 may be smaller than the fifth thickness t5. According to an embodiment, the fourth thickness t4 and the fifth thickness t5 may be the thicknesses at which resonance occurs, and the sixth thickness t6 may be the thickness at which resonance does not occur. The fifth light emission area ER5 may have resonant thickness, but it overlaps the light absorption layer LTL according to the embodiment, so most of the light may be absorbed by the light absorption layer LTL, and light reflection and light emission may hardly occur in the fifth light emission area ER5.

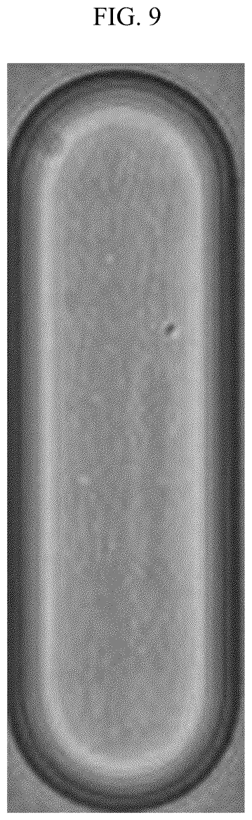

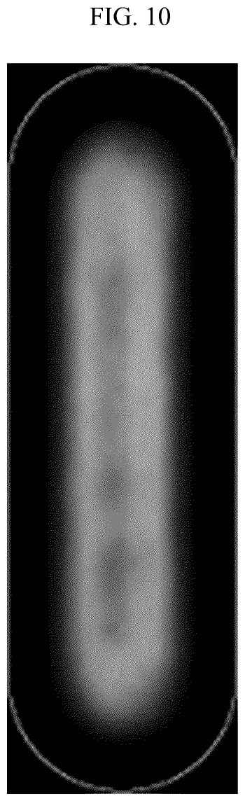

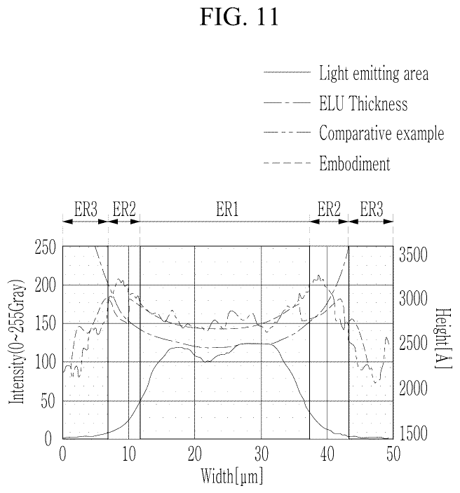

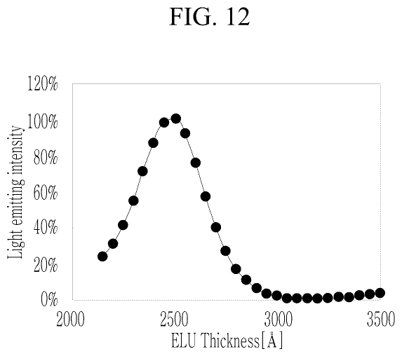

Below, an embodiment and a comparative example are described with reference to FIG. 9 to FIG. 12. FIG. 9 and FIG. 10 are each an image of a pixel according to a comparative example. FIG. 11 and FIG. 12 are characteristic graphs according to a comparative example and an embodiment.

FIG. 9 is a reflection image for the pixel that does not include a reflection layer according to the comparative example. It is confirmed that reflections occur frequently along the periphery of the wall due to differences in a reflectivity even in the pixel, resulting in the appearance of reflective bands of various colors.

However, according to an embodiment, by including the metal layer arranged to overlap the wall, light emission by resonance may be generated in that region, thereby reducing reflection from occurring around the wall.

FIG. 10 is a light emitting image for the pixel without a reflective layer according to a comparative example. It is confirmed that light emission does not occur along the periphery of the wall due to the difference in the thickness of the light emitting part in the pixel.

However, according to an embodiment, by including a reflective layer arranged to overlap the wall, light emission may occur because it is provided with the thickness in which a resonance phenomenon occurs even in some light emission areas that overlap the wall and the metal layer. For example, the light emission area in the pixel may increase.

Referring to FIG. 11, the light emission area of the pixel according to the comparative example corresponds to the first light emission area ER1. Except for the peripheral area ER3 covered by the shading layer, it is confirmed that in the second light emission area ER2 that overlaps with the wall, the thickness of the light emitting part did not match the selected resonance thickness, so almost no light was emitted.

For example, in case of looking at the reflectance of the pixel according to the embodiment, it may be seen that reflectance is reduced in the second light emission area ER2 of the light emitting part compared to reflectance of the pixel according to the comparative example. Therefore, in the second light emission area ER2 according to the embodiment, reflection may be reduced and light emission may be generated, so display quality may be improved.

Referring to FIG. 12, it may be seen that the light emitting intensity is relatively highest when the thickness of the light emitting part ELU is about 2500 Å according to the embodiment. In case that the thickness of the light emitting part ELU becomes much thicker or thinner than the thickness, light emitting intensity may decrease. For example, it may be seen that light emission is most effective when the resonance thickness is satisfied.

A display device according to an embodiment may be applied to various electronic devices. An electronic device according to an embodiment may include the display device, and may further include modules or devices having additional functions other than the display device.

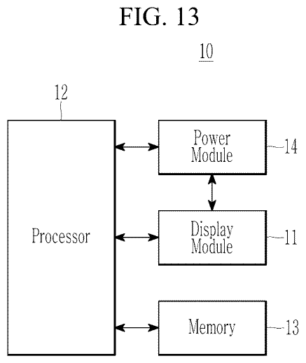

FIG. 13 is a block diagram of an electronic device according to an embodiment. Referring to FIG. 13, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 10 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device.

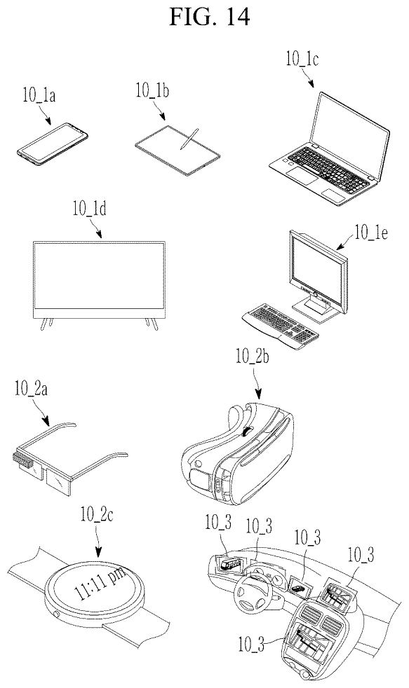

FIG. 14 shows schematic diagrams of electronic devices according to various embodiments.

Referring to FIG. 14, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

According to an embodiment, the thickness of the light emitting part ELU overlapping the wall and the thickness of the center portion of the light emitting part ELU may be substantially the same by providing the metal layer, so that luminous efficiency may be increased and the light emission area may be expanded.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A display device comprising:
a substrate,
a transistor disposed on the substrate,
a first electrode electrically connected to the transistor,
a metal layer disposed on the first electrode,
a wall disposed on the metal layer,
a light emitting part disposed in an opening formed by the metal layer and the wall, and
a second electrode disposed on the light emitting part, wherein
the light emitting part has a concave shape in the opening, and
an end portion of the metal layer and an end portion of the wall are aligned with each other.

2. The display device of claim 1, wherein
a first thickness of a central region of the light emitting part is substantially equal to a second thickness of the light emitting part that overlaps the metal layer.

3. The display device of claim 2, wherein
a first light emission area of the light emitting part having the first thickness is in contact with the first electrode.

4. The display device of claim 3, wherein
a second light emission area of the light emitting part having the second thickness is in contact with the wall.

5. The display device of claim 4, wherein
the light emitting part includes a peripheral area having a thickness smaller than the second thickness.

6. The display device of claim 5, wherein
using a center portion of the light emitting part as a reference, the first light emission area, the second light emission area, and the peripheral area are arranged in order.

7. The display device of claim 5, wherein
the first light emission area is separated from the wall and the metal layer in a thickness direction of the substrate.

8. The display device of claim 5, wherein
the wall includes a first region and a second region stacked in a thickness direction of the substrate.

9. The display device of claim 8, wherein
a side slope of the first region and a side slope of the second region are different from each other.

10. The display device of claim 1, wherein
the first electrode includes:
a first sub-layer,
a second sub-layer disposed on the first sub-layer, and
a third sub-layer disposed on the second sub-layer.

11. The display device of claim 10, wherein
the second sub-layer includes a metal.

12. The display device of claim 1, wherein
the light emitting part includes at least one of a hole injection layer, a hole transport layer, a light emitting layer, and an electron transport layer sequentially stacked on the first electrode.

13. The display device of claim 12, wherein
the light emitting part includes the hole injection layer, the hole transport layer, the light emitting layer, and the electron transport layer, and
adjacent light emitting parts between adjacent pixels being spaced apart from each other by the wall.

14. An electronic device comprising:
a display device to display an image based on input image data, the display device including:
a substrate,
a transistor disposed on the substrate,
a first electrode electrically connected to the transistor,
a light absorption layer disposed on the first electrode and including an opening,
a wall disposed on the light absorption layer and including an opening,
a light emitting part disposed in the opening of the light absorption layer and the opening of the wall, and
a second electrode disposed on the light emitting part, wherein
the light emitting part has a concave shape in the opening, and
an end portion of the light absorption layer and an end portion of the wall are aligned with each other.

15. The electronic device of claim 14, wherein
a thickness of a central region of the light emitting part is substantially equal to a thickness of the light emitting part that overlaps the light absorption layer.

16. The electronic device of claim 14, wherein
the wall includes a first region and a second region stacked in a thickness direction of the substrate.

17. The electronic device of claim 16, wherein
a side slope of the first region and a side slope of the second region are different from each other.

18. The electronic device of claim 14, wherein
the light absorption layer includes chromium.

19. The electronic device of claim 14, wherein
the light emitting part includes at least one of a hole injection layer, a hole transport layer, a light emitting layer, and an electron transport layer sequentially stacked on the first electrode.

20. The electronic device of claim 19, wherein
the light emitting part includes the hole injection layer, the hole transport layer, the light emitting layer and the electron transport layer, and
adjacent light emitting parts between adjacent pixels are separated from each other by the wall.
